(19) United States
(12) Patent Application Publication
(10) Pub. No.: US 2015/0362175 A1
(43) Pub. Date: Dec. 17, 2015

(54) SLUDGE-REDUCTION STEAM GENERATOR AND METHOD FOR MANUFACTURING TUBE PLATE OF SLUDGE-REDUCTION STEAM GENERATOR

(71) Applicant: HAN SANG KIM, DAEJEON-SI (KR)

(72) Inventor: HAN SANG KIM, DAEJEON-SI (KR)

(21) Appl. No.: 14/378,932

(22) PCT Filed: Feb. 22, 2012
(86) PCT No.: PCT/KR2012/001332

§ 371 Date: Aug. 23, 2014

(30) Foreign Application Priority Data
Feb. 15, 2012 (KR) 10-2012-0015321

(51) Int. Cl. F22B 37/10; C23C 16/50; F22B 37/54

(52) U.S. Cl. CPC F22B 37/107; F22B 37/54; C23C 16/50

(57) ABSTRACT

A sludge-reduction steam generator and a method for manufacturing a tubular plate for same, which can effectively remove sludge deposits from the inside of a steam generator of a pressurized light water reactor. The sludge-reduction steam generator comprises a plurality of U-shaped heat transfer pipes and one or more tubular plates coupled to the heat transfer pipes provide support thereto. The heat transfer pipes are disposed so that heat-exchange hot water flows in a pressure container. The tubular plates are coated with a ceramic material having the same surface electro-kinetic polarity as iron corrosion products in a predetermined range. This prevents the fixation of deposits on the surfaces of the tubular plates by inducing electrically repulsive power on the surfaces of the tubular plates with respect to the deposits and facilitates the removal of the deposits precipitated on the surfaces of the tubular plates by reducing surface friction force.

### TECHNICAL FIELD

The present invention relates to a sludge-reduction steam generator and a method for manufacturing a tubular plate for a sludge-reduction steam generator, which can effectively remove sludge deposits from the inside of a steam generator of a pressurized light water reactor.

### BACKGROUND ART

A pressurized light water reactor nuclear power plant produces electric power through the steps of transferring heat generated from nuclear fuel, heating water supplied from the secondary side to convert the water into steam and carrying out mechanical work in a turbine using steam.

A great deal of supplied water containing corrosion products of a system structure causes a phase change in the secondary side of the steam generator, and in this instance, the iron corrosion products contained in the supplied water are deposited in the lower part of the secondary side of the steam generator due to a low speed of a flow rate.

The iron corrosion products are composed of 95.8% of hematite (Fe203) and magnetite (Fe304) and metallic oxides, and such iron corrosion products promote corrosion of a heat transfer pipe of the steam generator. Especially, the iron corrosion products which are deposited on a heat transfer pipe supporting plate (tubular pipe) obstruct a flow channel of cooling water so as to cause oscillation of a water level of the steam generator, and hence, cause power-reduction operation or an unexpected stop of a nuclear power plant.

Hundreds of kilograms of such iron corrosion products are deposited in the lower part of the steam generator every year. Therefore, in order to remove the corrosion products deposited in the lower part of the steam generator, a steam generator blow-down system is operated to remove the corrosion products at the time of an overhaul, but it has a problem in that the corrosion products are not easily removed by the blow-down system because iron oxide is fixed on the floor of the steam generator.

Moreover, recently, a measure to prevent the iron corrosion products from being deposited in the lower part of the steam generator using a dispersing agent has been effectively used, but it also has several problems in that using the dispersing agent requires high costs and causes side effects of water pollution.

### DISCLOSURE

### Technical Problem

Accordingly, the present invention has been made in an effort to solve the above-mentioned problems occurring in the prior arts, and it is an object of the present invention to provide a sludge-reduction steam generator and a method for manufacturing a tubular plate for a sludge-reduction steam generator which can remarkably enhance a removal efficiency of corrosion products of a blow-down system of a steam generator in order to prevent deposition of iron corrosion products onto a tubular plate.

### Technical Solution

To achieve the above objects, the present invention provides a sludge-reduction steam generator including: a plurality of U-shaped heat transfer pipes disposed in such a way that heat-exchange hot water flows in a pressure container; and one or more tubular plates penetrated by and coupled to the heat transfer pipes so as to support the heat transfer pipes, wherein the tubular plates are provided with a coated layer which is coated with a ceramic material having the same surface electrokinetic polarity (zeta potential) as iron corrosion products in a predetermined range.

In another aspect of the present invention, the present invention provides a method for manufacturing tubular plates supporting a plurality of U-shaped heat transfer pipes, which are disposed in such a way that heat-exchange hot water flows in a pressure container, the method for manufacturing tubular plates for a sludge-reduction steam generator including the step of: coating a coated layer on the surface of the tubular plates which are completely molded by coating a ceramic material having the same surface electrokinetic polarity (zeta potential) as iron corrosion products in a predetermined range.

The coated layer is coated on the surface of the tubular plates which support the heat transfer pipes of the steam generator by the chemical vapor deposition (CVD) or the plasma vapor deposition.

The ceramic material is one of titanium ceramic (TiO₂) and zirconium ceramic (ZrO₂).

### Advantageous Effects

The sludge-reduction steam generator and the method for manufacturing the tubular plate for the sludge-reduction steam generator according to the preferred embodiment of the present invention can provide an effect that the coated layer made of titanium ceramic (TiO₂) or zirconium ceramic (ZrO₂) coated on the upper side of the heat transfer pipe supporting plates (tubular plate) below the steam generator prevents deposition of Fe203 and Fe304 which are the main ingredients of sludge of the secondary side of the steam generator and increases surface induction to thereby easily remove iron corrosion products by a blow-down system of the steam generator.

Furthermore, the sludge-reduction steam generator and the method for manufacturing the tubular plate for the sludge-reduction steam generator according to the preferred embodiment of the present invention can reduce blocking of a flow channel of the steam generator, reduce fouling of the heat transfer pipes of the steam generator and increase thermal efficiency through the effective removal of sludge of the steam generator.

Additionally, the sludge-reduction steam generator and the method for manufacturing the tubular plate for the sludge-reduction steam generator according to the preferred embodiment of the present invention can reduce a damage of the heat transfer pipes in the heat transfer pipe supporting plates (tubular plates) by the sludge.

In addition, sludge-reduction steam generator and the method for manufacturing the tubular plate for the sludge-reduction steam generator according to the preferred embodiment of the present invention can prevent corrosion of a gap between a tube of the steam generator and a tube seat to thereby increase the lifespan of the heat transfer pipes of the steam generator.

### DESCRIPTION OF DRAWINGS

FIG. 1 is a sectional view of a steam generator 1 according to a preferred embodiment of the present invention.

FIG. 2 is a plan view of a heat transfer pipe supporting plate (tubular plate) 3 cut along the line of I-I of FIG. 1.

FIG. 3 is a schematic sectional view of the tubular plate 3 having a ceramic coated later 30.

### MODE FOR INVENTION

Reference will be now made in detail to the preferred embodiment of the present invention with reference to the attached drawings.

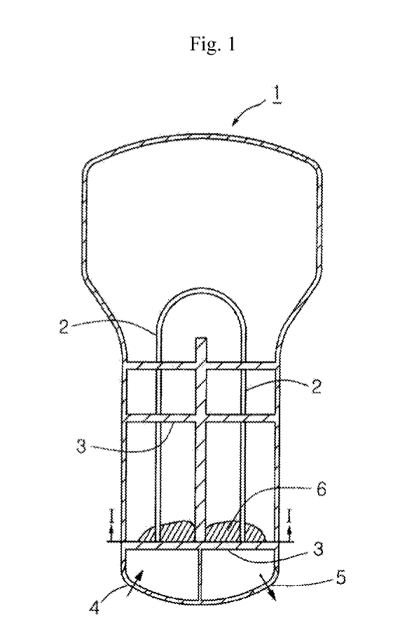

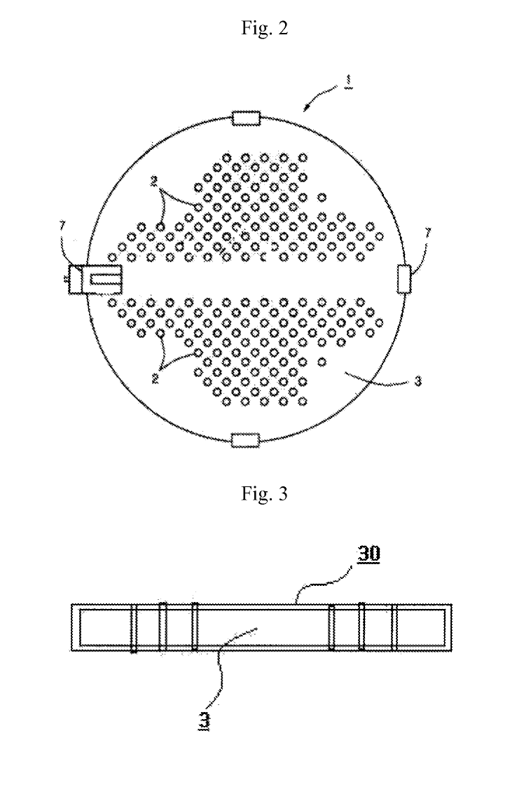

FIG. 1 is a sectional view of a steam generator 1 according to a preferred embodiment of the present invention, FIG. 2 is a plan view of a heat transfer pipe supporting plate (tubular plate) 3 cut along the line of I-I of FIG. 1, and FIG. 3 is a schematic sectional view of the tubular plate 3 having a ceramic coated later 30.

As shown in FIGS. 1 and 2, the sludge-reduction steam generator 1 includes: a plurality of U-shaped heat transfer pipes 2 disposed in such a way that heat-exchange hot water may flow in a pressure container; and one or more tubular plates 3 penetrated by and coupled to the heat transfer pipes 2 so as to support the heat transfer pipes 2, wherein the tubular plates 3, as shown in FIG. 3, are provided with a coated layer 30 which is coated with a ceramic material having the same surface electrokinetic polarity (zeta potential) as iron corrosion products in a predetermined range.

The pressurized container includes: a plurality of inlets 4 for introducing heated water thereinto; a plurality of outlets 5 for discharging water which moves through the heat transfer pipes 2 and is cooled after carrying out heat exchange; and a plurality of blow down ports 7 for removing deposits 6.

The ceramic material is one of titanium ceramic (TiO₂) and zirconium ceramic (ZrO₂).

The ceramic coated layer 30 is formed in such a way that TiO₂ or ZrO₂ which is a material existing stably in the high-temperature and high-pH environment of the secondary side of the steam generator is coated on the surface of the tubular plates 3 which support the heat transfer pipes 2 of the steam generator 1 by the chemical vapor deposition (CVD) or the plasma vapor deposition.

The secondary side of the steam generator 1 is operated under the high-temperature, high-pressure and high-pH environment. Therefore, an operation range of an electrochemical potential (ECP) may be varied from (+) tens of mVs to (−) 500 mVs. The zeta potential of Fe203 and Fe304 under temperature and pH for operating a general steam generator 1 is about −4 mVs, and TiO₂ or ZrO₂ under the same temperature and pH conditions has the same structure and similar potential.

The ceramic coated layer 30 is made of a material which can endure the change range of the ECP and the temperature change inside the steam generator 1 for a long time, and has the same polarity as magnetite of which zeta potential exists in a colloid state inside a dendrogram.

Therefore, the ceramic coated layer 30 which is made of TiO₂ or ZrO₂ causes electrically repulsive power against the deposits containing Fe203 and Fe304. Accordingly, because friction force between the surface of the coated layer 30 and the deposits is reduced, the ceramic coated layer 30 increases surface mobility of the deposits which are iron-containing foreign matters to thereby induce the deposits to be easily removed through the blow down ports 7 of the steam generator 1. Therefore, corrosion product removal efficiency of the blow down system of the steam generator is also remarkably enhanced.

1. A sludge-reduction steam generator comprising:
a plurality of U-shaped heat transfer pipes disposed so that heat-exchange hot water flows in a pressure container; and
one or more tubular plates coupled to the heat transfer pipes to support the heat transfer pipes,
wherein the tubular plates are coated with a ceramic material having a same surface electro-kinetic polarity as iron corrosion products in a predetermined range to provide a coated layer.

2. The sludge-reduction steam generator according to claim 1, wherein the ceramic material is one of titanium ceramic and zirconium ceramic.

3. A method for manufacturing tubular plates for supporting a plurality of U-shaped heat transfer pipes, comprising the steps of:
disposing the heat transfer pipes so that heat-exchange hot water flows in a pressure container
coating a layer on the surface of the tubular plate with ceramic material having a same surface electro-kinetic polarity as iron corrosion products in a predetermined range.

4. The method according to claim 3, wherein the coating step is carried by chemical vapor deposition process or plasma vapor deposition process.

5. The method according to claim 3, wherein the ceramic material is one of titanium ceramic and zirconium ceramic.
